(19) United States
(12) Patent Application Publication
(10) Pub. No.: US 2025/0275358 A1
(43) Pub. Date: Aug. 28, 2025

(54) DISPLAY DEVICE

(71) Applicant: LG Display Co., Ltd., Seoul (KR)

(72) Inventors: Jin-Uk Lee, Daegu (KR); Intae Ko, Daegu (KR)

(73) Assignee: LG Display Co., Ltd., Seoul (KR)

(21) Appl. No.: 19/035,285

(22) Filed: Jan. 23, 2025

(30) Foreign Application Priority Data
Feb. 28, 2024 (KR) 10-2024-0028661

(51) Int. Cl. H10K 59/121; G09G 3/3233; H10K 59/131; H10K 59/95

(52) U.S. Cl. CPC H10K 59/121; H10K 59/131; H10K 59/95; G09G 3/3233; G09G 2300/0426; G09G 2300/0842; G09G 2300/0861

(57) ABSTRACT

According to an aspect of the present disclosure, a display device includes: at least one sensor; and a display panel divided into a first display area overlapped with the at least one sensor and a second display area. In the first display area, a first pixel unit including at least one pixel and a transmission unit are disposed; in the second display area, a second pixel unit including at least one pixel is disposed; and the transmission unit is continuously disposed in a first direction and a second direction which is different from the first direction, thereby improving the modulation transfer function (MTF) characteristic of the sensor.

### CROSS-REFERENCE TO RELATED APPLICATION

This application claims the priority of Korean Patent Application No. 10-2024-0028661, filed on Feb. 28, 2024, in the Korean Intellectual Property Office, the disclosure of which is incorporated herein by reference.

### BACKGROUND

### Field

The present disclosure relates to a display device in which a sensor is disposed below a display area.

### Description of the Related Art

Recently, as it enters an information era, a display field which visually expresses electrical information signals has been rapidly developed and in response to this, various display devices having excellent performances, such as thin-thickness, light weight, and low power consumption, have been developed.

Unlike a liquid crystal display (LCD) device which includes a backlight, an organic light emitting display (OLED) device does not require a separate light source. Therefore, the organic light emitting display device can be manufactured to be light and thin and has process advantages and has low power consumption in accordance with the low voltage driving. First, the organic light emitting display device includes a self-emitting element and includes layers formed of organic thin films so that the flexibility and elasticity are superior to the other display devices and thus it is advantageous to be implemented as a flexible display device or a transparent display device.

In the meantime, the display device has a display area in which images are substantially displayed and a bezel area which is a non-display area which is blocked by a light shielding member so that images are not substantially displayed. In the display area, a display element is disposed to display images and in the bezel area, various wiring lines or driving circuits for driving the display element are disposed. The display device includes a camera, a speaker, and various sensors to provide various functions and these components are also disposed in the bezel area.

In recent years, in order to make the design of the display device beautiful and provide a larger screen in a limited size of the display device as large as possible, studies to reduce the bezel area are actively being conducted. In accordance with this, components, such as a camera or a sensor, which have been disposed in the bezel area in the related art are disposed in the display area, but in order to smoothly display images, a technique which disposes the components on a rear surface of the display panel is being proposed.

### SUMMARY

An object to be achieved by the present disclosure is to provide a display device which improves a modulation transfer function (MTF) characteristic of a sensor by means of a placement relationship of a transmission hole of a display panel which overlaps a sensor.

In addition, another object of the present disclosure is to provide a display device which maximizes or increases an opening area of a display panel by means of a placement relationship of a signal line disposed in the display panel.

Objects of the present disclosure are not limited to the above-mentioned objects, and other objects, which are not mentioned above, may be clearly understood by those skilled in the art from the following descriptions.

To achieve these and other objects of the present disclosure, and according to an aspect of the present disclosure, a display device includes at least one sensor; and a display panel divided into a first display area overlapped with the at least one sensor and a second display area, wherein: in the first display area, a first pixel unit including at least one pixel and a transmission unit are disposed; in the second display area, a second pixel unit including at least one pixel is disposed; and the transmission unit is continuously disposed in a first direction and a second direction which is different from the first direction, thereby improving the modulation transfer function (MTF) characteristic of the sensor.

In another aspect of the present disclosure, a display device includes at least one sensor; and a display panel including a plurality of gate lines extending in a first direction, a plurality of data lines extending in a second direction, and a plurality of pixels, wherein in a transmissive area of the display panel which overlaps the at least one sensor, a plurality of transmission holes are disposed in the first direction and the second direction, thereby improving the modulation transfer function (MTF) characteristic of the sensor.

Other detailed matters of various example embodiments are included in the detailed description and the drawings.

In the display device according to example embodiments of the present disclosure, a ratio of a transmission hole is maximized or increased to increase an amount of light which is detectable by a sensor, thereby improving a sensing performance of the sensor.

In the display device according to example embodiments of the present disclosure, transmission holes are disposed in a matrix to optimize the MTF, thereby optimizing an optical characteristic of the sensor.

The effects according to the present disclosure are not limited to the contents exemplified above, and more various effects are included in the present specification.

Additional features and aspects of the present disclosure are set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the present disclosure and are incorporated in and constitute a part of this application, illustrate aspects of the disclosure and together with the description serve to explain various principles of the present disclosure. In the drawings:

FIG. 1 is a view illustrating a front surface of a display device according to an example embodiment of the present disclosure and a corresponding side surface;

FIG. 2 is a circuit diagram of one sub pixel of a display device according to an example embodiment of the present disclosure;

FIG. 3 is a view schematically illustrating a second display area of a display panel of a display device according to an example embodiment of the present disclosure;

FIG. 4 is a view schematically illustrating a first display area of a display panel of a display device according to an example embodiment of the present disclosure;

FIG. 5 is a view illustrating a detailed layout of a first display area of a display panel of a display device according to an example embodiment of the present disclosure;

FIG. 6 is a cross-sectional view taken along the line VI-VI′ in FIG. 5;

FIG. 7 is a cross-sectional view taken along the line VII-VII′ in FIG. 5;

FIG. 8 is a cross-sectional view taken along the line VIII-VIII′ in FIG. 5;

FIG. 9 is a view illustrating a placement relationship of a transmission unit in a display device according to an example embodiment of the present disclosure;

FIGS. 10A and 10B are graphs illustrating a modulation transfer function (MTF) of a transmission unit TA in a display device according to an example embodiment of the present disclosure; and

FIG. 11 is a view illustrating a detailed layout of a first display area of a display panel of a display device according to another example embodiment of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more limiting term like “only”. Any references to singular may include plural, and vice versa, unless expressly stated otherwise.

Components are interpreted to include an ordinary error range even if not expressly stated.

Where the position relation between two parts is described using the terms such as “on”, “above”, “below”, and “next”, one or more parts may be positioned between the two parts unless the terms are used with a more limiting term “immediately” or “directly”.

Where an element or layer is disposed “on” another element or layer, another layer or another element may be interposed directly on the other element or therebetween.

Although the terms “first”, “second”, and the like may be used for describing various components, these components are not confined by these terms. These terms are merely used for referring to one component separately from the other components. Therefore, a first component to be mentioned below may be a second component, and vice versa, in a technical concept of the present disclosure.

Like reference numerals generally denote like elements throughout the specification unless otherwise specified.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

Hereinafter, example embodiments of the present disclosure will be described in detail with reference to the drawings.

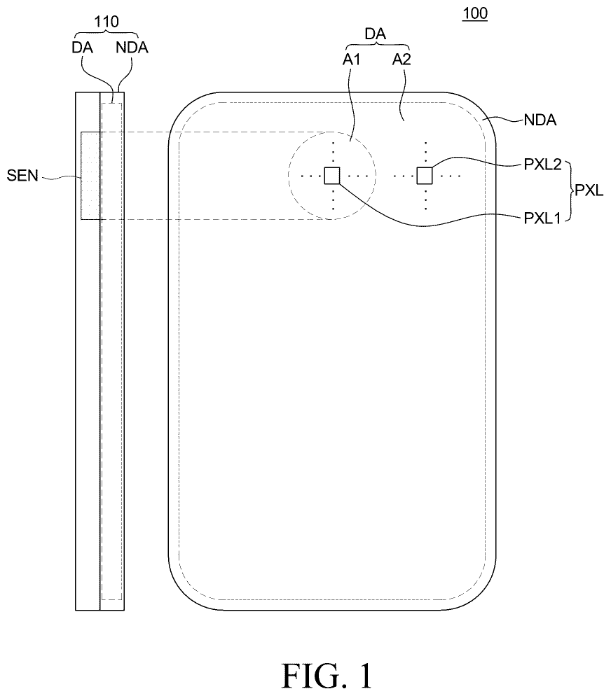

FIG. 1 is a view illustrating a front surface of a display device according to an example embodiment of the present disclosure and a corresponding side surface.

As shown in FIG. 1, a display device 100 according to an example embodiment of the present disclosure may include a display panel 110 and a sensor module SEN.

The display panel 110 (or a pixel unit or a display unit) may display an image. The display panel 110 may include various circuits, signal lines, and light emitting diodes disposed on the substrate. The display panel 110 is divided by a plurality of data lines and a plurality of gate lines which intersect each other and may include a plurality of pixels PXL connected to the plurality of data lines and the plurality of gate lines.

The display panel 110 may include a display area DA in which a plurality of pixels PXL is disposed to display images and a non-display area NDA which is located at the outside of the display area DA and includes various signal lines or pads. The display panel 110 may be implemented by a display panel used in various display devices, such as a liquid crystal display device, an organic light emitting display device, or an electrophoretic display device. Hereinafter, it is described that the display panel 110 is a panel used in the organic light emitting display device, but the example embodiment of the present disclosure is not limited thereto.

The display panel 110 may include a plurality of pixels PXL disposed on the display area DA. Each of the plurality of pixels PXL may be electrically connected to a corresponding gate line, among the gate lines, and a corresponding data line, among the data lines. Therefore, a gate signal and a data signal may be applied to each pixel PXL, through the gate line and the data line. Further, each pixel PXL may implement the gray scale by the applied gate signal and data signal and finally, the image may be displayed in the display area by the gray scales displayed by the pixels PXL.

Further, the display area DA may include a first display area A1 overlapped with the sensor module SEN and a second display area A2 which does not overlap the sensor module SEN. That is, the sensor module SEN may be disposed on a rear surface of the first display area A1.

Further, in the display area DA, the image needs to be displayed in the overall area so that at least one pixel PXL may be disposed in each of the first display area A1 and the second display area A2.

Specifically, a pixel disposed in the first display area A1 is referred to as a first pixel PXL1 and a pixel disposed in the second display area A2 is referred to as a second pixel PXL2.

Further, each of the plurality of pixels may include a plurality of sub pixels. Sub pixels included in one pixel PXL may emit different color light. For example, the sub pixels include a red sub pixel, a green sub pixel, and a blue sub pixel, but are not limited thereto and further includes a white sub pixel. The plurality of sub pixels may configure a pixel PXL.

To be more specific, in the first display area A1 which overlaps the sensor module SEN, light needs to be transmitted to the sensor module so that in the first display area A1, not only a plurality of first pixels PXL1 is disposed, but also a transmissive area for transmitting external light may be further included. In other words, in the first display area A1, a first pixel unit in which a plurality of first pixels PXL1 is disposed and a transmission unit (transmissive area) in which a pixel is not disposed are included.

Further, light does not need to be transmitted to the second display area A2 which does not overlap the sensor module SEN so that only the plurality of second pixels PXL2 may be disposed in the second display area A2. In other words, in the second display area A2, a second pixel unit in which the plurality of second pixels PXL2 is disposed may be included without including a transmission unit.

The sensor module SEN may be a camera which senses visible ray, but is not limited thereto and may include various sensors such as an IR sensor which senses infrared ray and a thermal sensor which senses heat.

The sensor module SEN may be disposed in a location corresponding to a transmission unit disposed in the first display area A1. That is, the sensor module may be disposed to overlap only the transmission unit disposed in the first display area A1, but is not limited thereto. The sensor module may be disposed to overlap not only the transmission unit disposed in the first display area A1 but also the first pixel unit.

The above-described transmission unit has a higher light transmittance than the other areas so that a sensor module provided in the corresponding location may detect more light which is incident onto the front surface than the other area. Accordingly, in the first display area A1, not only light which is incident onto the front surface is detected by the sensor module, but also image may be output through the first pixel unit disposed in the first display area A1.

In the meantime, the non-display area NDA is an area located in the vicinity of the display area DA and may refer to a remaining area excluding the display area DA. In the non-display area NDA, a data driver, a gate driver, and a timing controller may be disposed.

The timing controller (or a timing control circuit) may receive timing signals, such as a vertical synchronization signal, a horizontal synchronization signal, a data enable signal, or a dot clock by means of a receiving circuit such as an LVDS or TMDS interface connected to the outside (for example, a host system). The timing controller may generate and output timing control signals to control the data driver and the gate driver based on the input timing signal.

The data driver (or a data driving circuit) may supply a data signal to the plurality of pixels. To this end, the data driver may include at least one source drive IC (integrated circuit). The source drive IC may be supplied with digital video data and a source timing control signal from the timing controller. The source drive IC converts digital video data into a gamma voltage in response to a source timing control signal to generate a data signal and may supply the data signal to the pixels through the data lines of the display panel 110. The source drive IC may be connected to the data line of the display panel 110 by a chip on glass (COG) process or a tape automated bonding (TAB) process. Further, the source drive IC may be formed on the display panel 110 or is formed on a separate PCB substrate to be connected to the display panel 110.

The gate driver (or a gate driving circuit, a scan driver, or a scan driving circuit) may supply a gate signal to the plurality of sub pixels. The gate driver may include a level shifter and a shift register. The level shifter shifts a level of a clock signal input at a transistor-transistor-logic (TTL) level from the timing controller and then supplies the clock signal to the shift register. The shift register may be formed in the non-display area NDA of the display panel, by a GIP manner, but is not limited thereto. The shift register may be configured by a plurality of stages which shifts and outputs the gate signal, in response to the clock signal and the driving signal. The plurality of stages included in the shift register may sequentially output the gate signal through a plurality of output terminals.

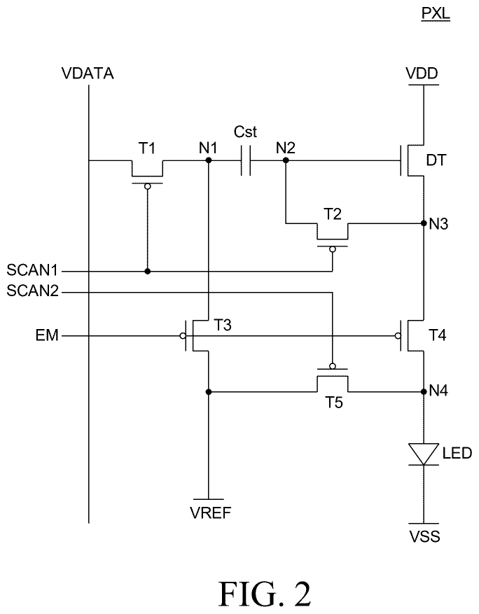

FIG. 2 is a circuit diagram of one sub pixel of a display device according to an example embodiment of the present disclosure.

In FIG. 2, it is illustrated that a pixel circuit disposed in one sub pixel is a 6T1C pixel circuit structure configured by six transistors and one capacitor, but this is illustrative and the number of transistors and the number of capacitors which configure the pixel circuit are not limited thereto.

As shown in FIG. 2, one pixel circuit includes a first transistor T1, a second transistor T2, a third transistor T3, a fourth transistor T4, a fifth transistor T5, a driving transistor DT, a storage capacitor Cst, and a light emitting diode LED.

The light emitting diode LED emits light by a driving current supplied from the driving transistor DT. An anode of the light emitting diode LED is connected to a fourth node N4 and a cathode of the light emitting diode LED is connected to an input terminal of a low potential voltage VSS.

The driving transistor DT controls a driving current applied to the light emitting diode LED in accordance with a voltage between a source electrode and a gate electrode. The source electrode of the driving transistor DT is connected to an input terminal of a high potential voltage VDD, a gate electrode is connected to a second node N2, and a drain electrode is connected to a third node N3.

The first transistor T1 includes a gate electrode connected to an input terminal of the first scan signal SCAN1, a source electrode connected to a data line DL which supplies a data voltage VDATA, and a drain electrode connected to the first node N1. The first transistor T1 may apply the data voltage VDATA supplied from the data line DL to the first node N1 in response to a first scan signal SCAN1.

The second transistor T2 includes a source electrode connected to the third node N3, a drain electrode connected to the second node N2, and a gate electrode connected to an input terminal of the first scan signal SCAN1. The second transistor T2 may form a diode-connection of a gate electrode and a drain electrode of the driving transistor DT, in response to the first scan signal SCAN1.

The third transistor T3 includes a gate electrode connected to an input terminal of the emission signal EM, a source electrode connected to the first node N1, and a drain electrode connected to an input terminal of the reference voltage VREF. The third transistor T3 may apply a reference voltage VREF to the first node N1 in response to an emission signal EM.

The fourth transistor T4 includes a source electrode connected to the third node N3, a drain electrode connected to the fourth node N4, and a gate electrode connected to an input terminal of the emission signal EM. The fourth transistor T4 forms a current path between the third node N3 and the fourth node N4, in response to the emission signal EM.

The fifth transistor T5 includes a drain electrode connected to the fourth node N4, a source electrode connected to an input terminal of the reference voltage VREF, and a gate electrode connected to an input terminal of the second scan signal SCAN2. The fifth transistor T5 may apply a reference voltage VREF to the fourth node N4 in response to the second scan signal SCAN2.

The storage capacitor Cst includes a first electrode connected to the first node N1 and a second electrode connected to the second node N2.

In the display device 100, one frame period may be divided into an initial period, a sampling period, and an emission period. The initial period is a period when the gate voltage of the driving transistor DT is initialized. The sampling period is a period when a voltage of the anode of the light emitting diode LED is initialized and a threshold voltage of the driving transistor DT is sampled to be stored in the second node N2. The emission period is a period when a sampled threshold voltage is included to program a voltage between a source electrode and a gate of the driving transistor DT and the light emitting diode LED emits light with a driving current according to the programmed voltage.

Here, during the emission period, the emission signal EM is inverted into a gate-on voltage. That is, the emission signal EM falls to the gate-on voltage. Therefore, the fourth transistor T4 is turned on by the emission signal EM and a driving current for driving the light emitting diode LED is applied to the light emitting diode LED via the fourth node N4. Therefore, during the emission period, the light emitting diode LED may emit light. In the present disclosure, even though it is described that a gate-on voltage is a gate low voltage and a gate-off voltage is a gate high voltage, a gate-on voltage may be a gate high voltage and a gate-off voltage may be a gate low voltage according to a type of the transistor.

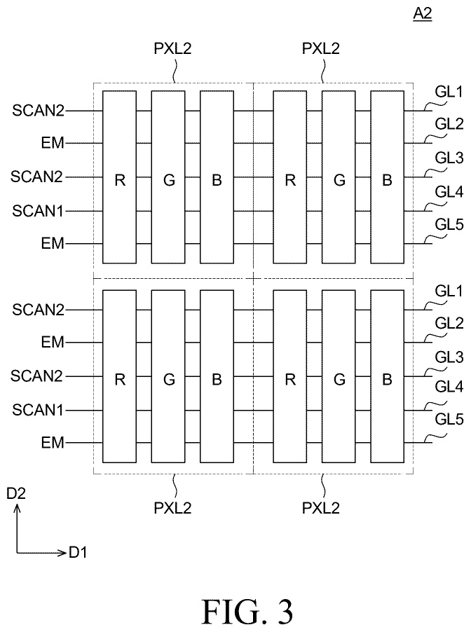

FIG. 3 is a view schematically illustrating a second display area of a display panel of a display device according to an example embodiment of the present disclosure.

As described above, in the second display area A2, a plurality of second pixels PXL2 may be disposed. Accordingly, even though in FIG. 2, a plurality of second pixels PXL2 disposed in a 2×2 matrix is illustrated, the number of the plurality of second pixels PXL2 is not limited thereto, but may vary in various forms.

Further, a plurality of signal lines extending in a first direction D1 may be connected to the plurality of second pixels PXL2 disposed in the first direction D1.

To be more specific, the plurality of gate lines GL1 to GL5 extends in the first direction D1 to be connected to sub pixels R, G, and B of the plurality of second pixels PXL2 disposed in the first direction D1.

For example, the plurality of gate lines GL1 to GL5 may include a first gate line GL1 to a fifth gate line GL5. Further, the second scan signal SCAN2 is applied to the first gate line GL1, the emission signal EM is applied to the second gate line GL2, the second scan signal SCAN2 is applied to the third gate line GL3, the first scan signal SCAN1 is applied to the fourth gate line GLA, and the emission signal EM is applied to the fifth gate line GL5.

Therefore, in the second display area A2, the second scan signal SCAN2 may be applied to each of the plurality of sub pixels R, G, and B of the second pixel PXL2 through the first gate line GL1. Further, in the second display area A2, the emission signal EM may be applied to each of the plurality of sub pixels R, G, and B of the second pixel PXL2 through the second gate line GL2. Further, in the second display area A2, the second scan signal SCAN2 may be applied to each of the plurality of sub pixels R, G, and B of the second pixel PXL2 through the third gate line GL3. Further, in the second display area A2, the first scan signal SCAN1 may be applied to each of the plurality of sub pixels R, G, and B of the second pixel PXL2 through the fourth gate line GLA. Further, in the second display area A2, the emission signal EM may be applied to each of the plurality of sub pixels R, G, and B of the second pixel PXL2 through the fifth gate line GL5.

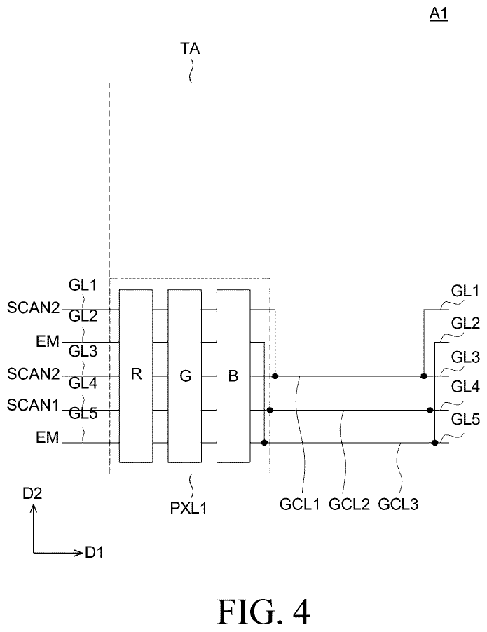

FIG. 4 is a view schematically illustrating a first display area of a display panel of a display device according to an example embodiment of the present disclosure.

As described above, in the first display area A1, the first pixel PXL1 and the transmission unit TA may be disposed.

Further, the plurality of signal lines extending in the first direction D1 may be connected to the first pixel PXL1.

To be more specific, the plurality of gate lines GL1 to GL5 extends in the first direction D1 to be connected to sub pixels R, G, and B of the first pixel PXL1.

For example, the plurality of gate lines GL1 to GL5 may include a first gate line GL1 to a fifth gate line GL5. Further, the second scan signal SCAN2 is applied to the first gate line GL1, the emission signal EM is applied to the second gate line GL2, the second scan signal SCAN2 is applied to the third gate line GL3, the first scan signal SCAN1 is applied to the fourth gate line GL4, and the emission signal EM is applied to the fifth gate line GL5.

Therefore, in the first display area A1, the second scan signal SCAN2 may be applied to each of the plurality of sub pixels R, G, and B of the first pixel PXL1 through the first gate line GL1. Further, in the first display area A1, the emission signal EM may be applied to each of the plurality of sub pixels R, G, and B of the first pixel PXL1 through the second gate line GL2. Further, in the first display area A1, the second scan signal SCAN2 may be applied to each of the plurality of sub pixels R, G, and B of the first pixel PXL1 through the third gate line GL3. Further, in the first display area A1, the first scan signal SCAN1 may be applied to each of the plurality of sub pixels R, G, and B of the first pixel PXL1 through the fourth gate line GL4. Further, in the first display area A1, the emission signal EM may be applied to each of the plurality of sub pixels R, G, and B of the first pixel PXL1 through the fifth gate line GL5.

Further, a signal connection line which extends in the first direction D1 to be electrically connected to the plurality of signal lines may be disposed in the transmission unit TA.

To be more specific, a plurality of gate connection lines GCL1, GCL2, and GCL3 extends in the first direction D1 to be connected to the plurality of gate lines GL1 to GL5. Further, any one of the plurality of gate connection lines GCL1, GCL2, and GCL3 may be connected to the plurality of gate lines GL1 to GL5 which transmits the same signal.

Therefore, the number of the plurality of gate connection lines GCL1, GCL2, and GCL3 may be smaller than the number of the plurality of gate lines GL1 to GL5.

For example, the plurality of gate connection lines GCL1, GCL2, and GCL3 may include a first gate connection line GCL1 to a third gate connection line GCL3. Further, the first gate line GL1 and the third gate line GL3 to which the second scan signal SCAN2 is applied may be connected to the first gate connection line GCL1. Further, the fourth gate line GL4 to which the first scan signal SCAN1 is applied may be connected to the second gate connection line GCL2. Further, the second gate line GL2 and the fifth gate line GL5 to which the emission signal EM is applied may be connected to the third gate connection line GCL3.

In other words, in the first display area A1, the first gate line GL1 and the third gate line GL3 may be integrated to the first gate connection line GCL1. Further, in the first display area A1, the second gate line GL2 and the fifth gate line GL5 may be integrated to the third gate connection line GCL3 of the first display area A1.

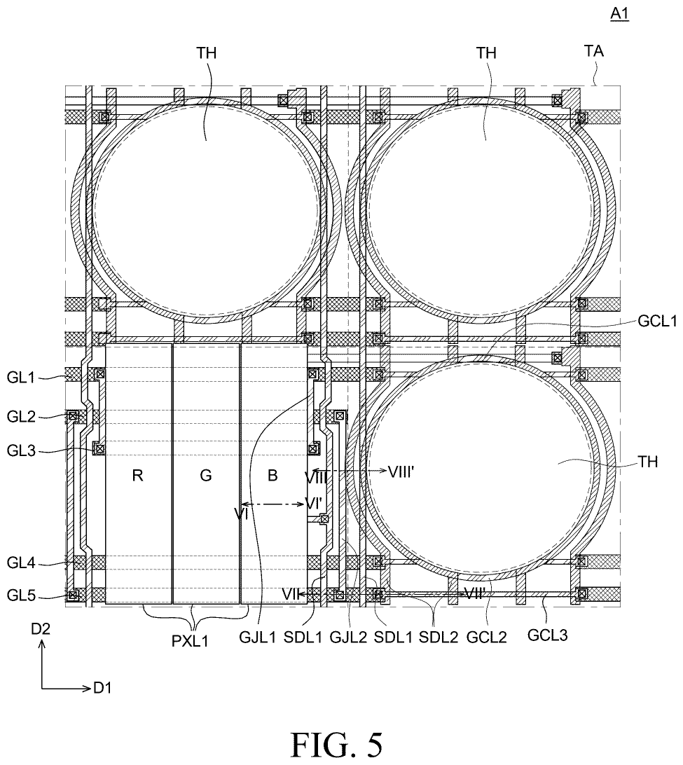

FIG. 5 is a view illustrating a detailed layout of a first display area of a display panel of a display device according to an example embodiment of the present disclosure.

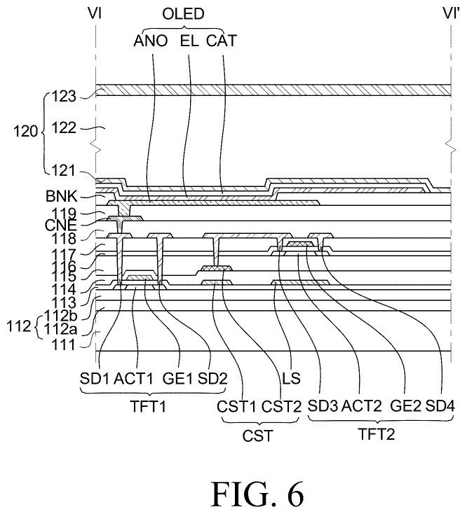

FIG. 6 is a cross-sectional view taken along the line VI-VI′ in FIG. 5.

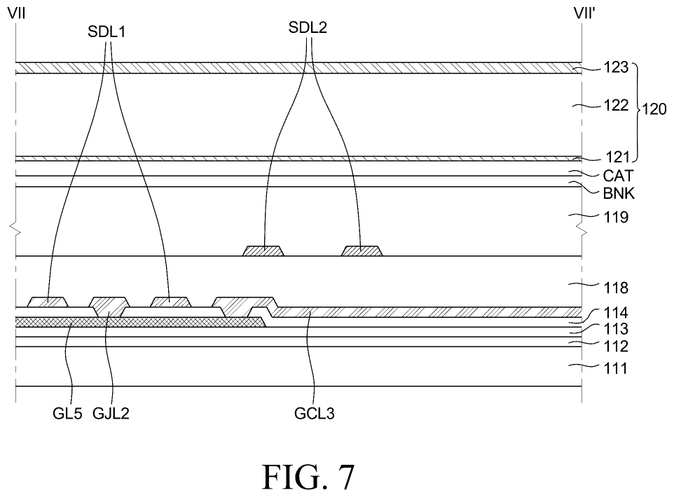

FIG. 7 is a cross-sectional view taken along the line VII-VII′ in FIG. 5.

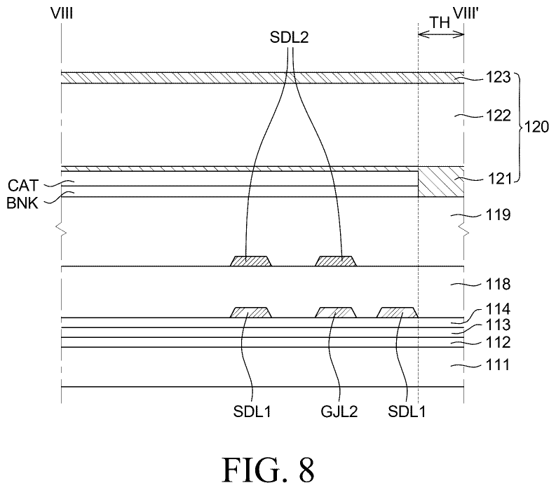

FIG. 8 is a cross-sectional view taken along the line VIII-VIII′ in FIG. 5.

In FIG. 5, a part of the plurality of gate lines GL1 to GL5 which overlaps the plurality of sub pixels R, G, and B is denoted with a dotted line.

That is, FIG. 6 is a cross-sectional view illustrating a laminated structure of a display device according to an example embodiment.

FIG. 6 is a cross-sectional view including two switching thin film transistors TFT1 and TFT2 and one storage capacitor CST. Two thin film transistors TFT1 and TFT2 include any one thin film transistor of a switching thin film transistor or a driving transistor including a polycrystalline semiconductor material, and an oxide thin film transistor TFT2 including an oxide semiconductor material. In this case, the thin film transistor including the polycrystalline semiconductor material is referred to as a polycrystalline thin film transistor TFT1 and the thin film transistor including the oxide semiconductor material is referred to as an oxide thin film transistor TFT2.

The polycrystalline thin film transistor TFT1 illustrated in FIG. 6 is an emission switching thin film transistor connected to the light emitting diode OLED and the oxide thin film transistor TFT2 is a driving transistor or any one switching thin film transistor connected to the storage capacitor CST.

One pixel PXL includes the light emitting diode OLED and a pixel driving circuit which applies a driving current to the light emitting diode OLED. The pixel driving circuit is disposed on the substrate 111 and the light emitting diode OLED is disposed on the pixel driving circuit. Further, an encapsulation layer 120 is disposed on the light emitting diode OLED. The encapsulation layer 120 protects the light emitting diode OLED.

The pixel driving circuit may refer to one pixel array unit including a driving thin film transistor, a switching thin film transistor, and a capacitor. Further, the light emitting diode OLED may refer to an array unit which includes an anode electrode and a cathode electrode and an emission layer disposed therebetween to emit light.

In one example embodiment, the driving thin film transistor and at least one switching thin film transistor use the oxide semiconductors as active layers. The thin film transistor which uses the oxide semiconductor material as an active layer has an excellent leakage current blocking effect and has a manufacturing cost which is relatively cheaper than a thin film transistor which uses a polycrystalline semiconductor material as an active layer. Accordingly, to reduce the power consumption and save the manufacturing cost, the pixel driving circuit according to the example embodiment includes a driving thin film transistor and at least one switching thin film transistor which use the oxide semiconductor material.

All the thin film transistors which configure the pixel driving circuit may be implemented using the oxide semiconductor material or only some switching thin film transistor may be implemented using the oxide semiconductor material.

However, it is difficult to ensure the reliability with the thin film transistor using the oxide semiconductor material, but the thin film transistor using a polycrystalline semiconductor material has a rapid operation speed and excellent reliability. Accordingly, the example embodiment includes both the switching thin film transistor using the oxide semiconductor material and the switching thin film transistor using a polycrystalline semiconductor material.

The substrate 111 may be configured as a multi-layer in which an organic film and an inorganic film are alternately laminated. For example, in the substrate 111, an organic film such as polyimide and an inorganic film such as silicon oxide SiO₂ may be alternately laminated.

A lower buffer layer 112a is formed on the substrate 111. The lower buffer layer 112a is provided to block moisture penetrating from the outside and may be configured by laminating a plurality of silicon oxide (SiO₂) films. An auxiliary buffer layer 112b may be further disposed on the lower buffer layer 112a to protect the element from the moisture permeation.

The polycrystalline thin film transistor TFT1 is formed on the substrate 111. The polycrystalline thin film transistor TFT1 may use the polycrystalline semiconductor as an active layer. The polycrystalline thin film transistor TFT1 includes a first active layer ACT1 including a channel through which electrons or holes move, a first gate electrode GE1, a first source electrode SD1, and a first drain electrode SD2.

The first active layer ACT1 includes a first channel region, a first source region which is disposed at one side of the first channel region and a first drain region disposed at the other side. The first channel region is disposed between the first source region and the first drain region.

The first source region and the first drain region are regions in which an intrinsic polycrystalline semiconductor material is doped with group 5 or group 3 impurity ions, for example, phosphorus (P) or boron (B) at a predetermined concentration to be conductive. In the first channel region, the polycrystalline semiconductor material maintains an intrinsic state and a path through which the electrons or holes move is provided.

In the meantime, the polycrystalline thin film transistor TFT1 includes a first gate electrode GE1 which overlaps the first channel region of the first active layer ACT1. A first gate insulating layer 113 is disposed between the first gate electrode GE1 and the first active layer ACT1. The first gate insulating layer 113 may be configured by laminating inorganic layers, such as a silicon oxide (SiO₂) film or silicon nitride (SiNx) as a single layer or a plurality of layers.

In the example embodiment, the polycrystalline thin film transistor TFT1 has a top gate structure in which the first gate electrode GE1 is located above the first active layer ACT1. Accordingly, a first electrode CST1 included in a storage capacitor CST and a light shielding layer LS included in the oxide thin film transistor TFT2 are formed with the same material as the first gate electrode GE1. The first gate electrode GE1, the first electrode CST1, and the light shielding layer LS are formed by one mask process so that the number of mask processes may be reduced.

The first gate electrode GE1 is configured by a metal material. For example, the first gate electrode GE1 may be a single layer or a plurality of layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

A first interlayer insulating layer 114 is disposed on the first gate electrode GE1. The first interlayer insulating layer 114 may be configured by silicon oxide (SiO₂) or silicon nitride (SiNx).

The display panel may further include an upper buffer layer 115, a second gate insulating layer 116, and a second interlayer insulating layer 117 which are sequentially disposed on the first interlayer insulating layer 114. The polycrystalline thin film transistor TFT1 includes the first source electrode SD1 and the first drain electrode SD2 which are formed on the second interlayer insulating layer 117 and are connected to the first source region and the first drain region, respectively.

The first source electrode SD1 and the first drain electrode SD2 may be a single layer or a plurality of layers formed of any one of molybdenum (Mo), aluminum (Al), chrome (Cr), gold (Au), titanium (Ti), nickel (Ni), neodymium (Nd), and copper (Cu) or an alloy thereof, but are not limited thereto.

The upper buffer layer 115 separates the second active layer ACT2 of the oxide thin film transistor TFT2 implemented by an oxide semiconductor material from the first active layer ACT1 implemented by a polycrystalline semiconductor material and provides a base for forming the second active layer ACT2.

The second gate insulating layer 116 covers the second active layer ACT2 of the oxide thin film transistor TFT2. The second gate insulating layer 116 is formed on the second active layer ACT2 implemented by the oxide semiconductor material so that the second gate insulating layer is implemented by an inorganic film. For example, the second gate insulating layer 116 may be silicon oxide (SiO₂) or silicon nitride (SiNx).

The second gate electrode GE2 is configured by a metal material. For example, the second gate electrode GE2 may be a single layer or a plurality of layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

In the meantime, the oxide thin film transistor TFT2 includes a second active layer ACT2 which is formed on the upper buffer layer 115 and is implemented by an oxide semiconductor material, a second gate electrode GE2 disposed on the second gate insulating layer 116, and a second source electrode SD3 and a second drain electrode SD4. The second source electrode SD3 and the second drain electrode SD4 are disposed on the second interlayer insulating layer 117.

The second active layer ACT2 includes an intrinsic second channel region which is implemented by the oxide semiconductor material and is not doped with an impurity and a second source region and a second drain region which are doped with an impurity to become conductive.

The oxide thin film transistor TFT2 further includes a light shielding layer LS which is located below the upper buffer layer 115 and overlaps the second active layer ACT2. A light shielding layer LS blocks light incident onto the second active layer ACT2 to ensure the reliability of the oxide thin film transistor TFT2. The light shielding layer LS is formed by the same material as the first gate electrode GE1 and is formed on an upper surface of the first gate insulating layer 113. The light shielding layer LS is electrically connected to the second gate electrode GE2 to configure a dual gate.

The second source electrode SD3 and the second drain electrode SD4 are simultaneously formed of the same material as the first source electrode SD1 and the first drain electrode SD2 on the second interlayer insulating layer 117 to reduce the number of mask processes.

In the meantime, a second electrode CST2 is disposed on the first interlayer insulating layer 114 so as to overlap the first electrode CST1 to implement the storage capacitor CST. For example, the second electrode CST2 may be a single layer or a plurality of layers formed of any one of molybdenum (Mo), aluminum (Al), chrome (Cr), gold (Au), titanium (Ti), nickel (Ni), neodymium (Nd), and copper (Cu), or an alloy thereof.

The storage capacitor CST stores a data voltage which is applied through the data line DL for a predetermined period and then supplies the data voltage to the light emitting diode OLED. The storage capacitor CST includes two corresponding electrodes and a dielectric material disposed therebetween. The first interlayer insulating layer 114 is located between the first electrode CST1 and the second electrode CST2.

The first electrode CST1 or the second electrode CST2 of the storage capacitor CST may be electrically connected to the second source electrode SD3 or the second drain electrode SD4 of the oxide thin film transistor TFT2. However, it is not limited thereto, and a connection relationship of the storage capacitor CST may vary according to the pixel driving circuit.

In the meantime, a first planarization layer 118 and a second planarization layer 119 are sequentially disposed on the pixel driving circuit to planarize an upper end of the pixel driving circuit. The first planarization layer 118 and the second planarization layer 119 may be organic films, such as polyimide or acryl resin.

Further, the light emitting diode OLED is formed on the second planarization layer 119.

The light emitting diode OLED includes an anode electrode ANO, a cathode electrode CAT, and an emission layer EL disposed between the anode electrode ANO and the cathode electrode CAT. If a pixel driving circuit which commonly uses a low potential voltage connected to the cathode electrode CAT is implemented, the anode electrode ANO is disposed as a separate electrode in every sub pixel. If a pixel driving circuit which commonly uses a high potential voltage is implemented, the cathode electrode CAT may be disposed as a separate electrode in every sub pixel.

The light emitting diode OLED is electrically connected to the driving element through an intermediate electrode CNE disposed on the first planarization layer 118. Specifically, the anode electrode ANO of the light emitting diode OLED and the first source electrode SD1 of the polycrystalline thin film transistor TFT1 which configures the pixel driving circuit are connected to each other by the intermediate electrode CNE.

The anode electrode ANO is connected to the intermediate electrode CNE exposed through the contact hole which passes through the second planarization layer 119. Further, the intermediate electrode CNE is connected to the first source electrode SD1 exposed through the contact hole which passes through the first planarization layer 118.

The intermediate electrode CNE serves as a medium connecting the first source electrode SD1 and the anode electrode ANO. The intermediate electrode CNE may be formed of a conductive material, such as copper (Cu), silver (Ag), molybdenum (Mo), or titanium (Ti).

The anode electrode ANO may be formed to have a multi-layered structure including a transparent conductive film having high reflection efficiency and an opaque conductive film. The transparent conductive film is configured with a material having a relatively high work function, such as indium-tin-oxide (ITO) or indium-zinc-oxide (IZO). The opaque conductive film is configured as a single-layered or multilayered structure including aluminum (Al), silver (Ag), copper (Cu), lead (Pb), molybdenum (Mo), titanium (Ti), or an alloy thereof. For example, the anode electrode ANO is formed with a structure in which a transparent conductive film, an opaque conductive film, and a transparent conductive film are sequentially laminated or may be formed with a structure in which a transparent conductive film and an opaque conductive film are sequentially laminated.

The emission layer EL may be formed by laminating a hole related layer, an organic emission layer, and an electron related layer on the anode electrode ANO in this order or in a reverse order.

A bank layer BNK may be a pixel definition film which exposes the anode electrode ANO of each pixel PXL. The bank layer BNK may be formed of an opaque (for example, black) material to suppress the light interference between adjacent pixels PXL. In this case, the bank layer BNK includes a light shielding material which is formed of at least any one of a color pigment, organic black, and carbon. A spacer may be further disposed on the bank layer BNK.

The cathode electrode CAT is formed on the top surface and the side surface of the emission layer EL so as to be opposite to the anode electrode ANO with the emission layer EL therebetween. The cathode electrode CAT is integrally formed on the entire display area DA. When the cathode electrode CAT is applied to a top-emission type organic light emitting display device, the cathode electrode may be configured by a transparent conductive layer, such as indium-tin-oxide (ITO) or indium-zinc-oxide (IZO).

The encapsulation layer 120 may be further disposed on the cathode electrode CAT to suppress moisture permeation.

The encapsulation layer 120 may block moisture or oxygen from being permeated into the light emitting diode OLED which is vulnerable to the moisture or oxygen from the outside. To this end, the encapsulation layer 120 may include at least one inorganic encapsulation layer and at least one organic encapsulation layer, but is not limited thereto. In the present disclosure, a structure of the encapsulation layer 120 in which a first encapsulation layer 121, a second encapsulation layer 122, and a third encapsulation layer 123 are sequentially laminated will be described as an example.

The first encapsulation layer 121 is formed on the substrate 111 on which the cathode electrode CAT is formed. The third encapsulation layer 123 is formed on the substrate 111 on which the second encapsulation layer 122 is formed and encloses a top surface, a bottom surface, and a side surface of the second encapsulation layer 122 together with the first encapsulation layer 121. The first encapsulation layer 121 and the third encapsulation layer 123 may minimize or suppress the permeation of external moisture or oxygen into the light emitting diode OLED. The first encapsulation layer 121 and the third encapsulation layer 123 may be formed of an inorganic insulating material on which low-temperature deposition is allowed, such as silicon nitride (SiNx), silicon oxide (SiOx), silicon oxynitride (SiON), or aluminum oxide (Al₂O₃). The first encapsulation layer 121 and the third encapsulation layer 123 are deposited under a low temperature atmosphere so that the damage of the light emitting diode OLED which is vulnerable to a high temperature atmosphere may be suppressed during the deposition process of the first encapsulation layer 121 and the third encapsulation layer 123.

The second encapsulation layer 122 serves as a buffer which alleviates stress between layers due to the bending of the display device 100 and may planarize the step between layers. The second encapsulation layer 122 may be formed of acryl resin, epoxy resin, phenolic resin, polyamide resin, polyimide resin, polyethylene or a non-photosensitive organic insulating material such as silicon oxygen carbon (SiOC), or a photosensitive organic insulating material such as photoacryl, on the substrate 111 on which the first encapsulation layer 121 is formed, but is not limited thereto.

Among the plurality of signal lines, signal lines configured to output the same signal may be connected by a signal jumping line.

In the meantime, as shown in FIG. 5, gate lines configured to output the same gate signal, among the plurality of gate lines GL1 to GL5 extending in the first direction D1 may be connected by a plurality of gate jumping lines GJL1 and GJL2 extending in the second direction.

Specifically, the first gate line GL1 and the third gate line GL3 extending in the first direction D1 are connected by a first gate jumping line GJL1 extending in the second direction D2. Further, the first gate line GL1 and the third gate line GL3 connected by the first gate jumping line GJL1 are connected to the first gate connection line GCL1 extending in the first direction D1. Therefore, all the first gate line GL1 and the third gate line GL3, the first gate jumping line GJL1, and the first gate connection line GCL1 may transmit the second scan signal SCAN2.

Further, the second gate line GL2 and the fifth gate line GL5 extending in the first direction D1 are connected by a second gate jumping line GJL2 extending in the second direction D2. Further, the second gate line GL2 and the fifth gate line GL5 connected by the second gate jumping line GJL2 are connected to the third gate connection line GCL3 extending in the first direction D1. Therefore, all the second gate line GL2 and the fifth gate line GL5, the second gate jumping line GJL2, and the third gate connection line GCL3 may transmit the emission signal EM.

As shown in FIG. 7, the gate line GL5 may be disposed on the first gate insulating layer 113. Further, a metal layer on which the first gate electrode GE1 and the gate line GL5 are disposed is defined as a first layer. Further, on the first layer, the first interlayer insulating layer 114 which insulates the gate line GL5 and the first data line SDL1 disposed on the first layer may be disposed.

Further, as shown in FIG. 8, a metal layer on which the first data line SDL1 is disposed may be defined as a second layer. The above-described first data line SDL1 may be disposed on the same layer as the first source electrode SD1 and the first drain electrode SD2 and the second source electrode SD3 and the second drain electrode SD4 which have been described in FIG. 6.

Further, the first planarization layer 118 is disposed on the first data line SDL1 disposed on the second layer. The first planarization layer 118 planarizes an upper portion of the first data line SDL1 disposed on the second layer. Further, the first planarization layer 118 insulates the first data line SDL1 disposed on the second layer and the second data line SDL2 disposed on the third layer.

That is, a metal layer on which the second data line SDL2 is disposed may be defined as a third layer. Further, the second data line SDL2 may be formed on the same layer as the intermediate electrode CNE described in FIG. 6.

However, a voltage which is applied to the first data line SDL1 and the second data line SDL2 may be various voltages, such as a reference voltage VREF, a high potential voltage VDD, and a low potential voltage VSS, without being limited to the data voltage VDATA.

Further, the second planarization layer 119 is disposed on the second data line SDL2 disposed on the third layer. The second planarization layer 119 planarizes an upper portion of the second data line SDL2 disposed on the third layer.

Further, the bank layer BNK and the cathode electrode CAT may be formed on the second planarization layer 119 in an area excluding the transmission hole TH.

Further, the encapsulation layer 120 in which a first encapsulation layer 121, a second encapsulation layer 122, and a third encapsulation layer 123 are sequentially laminated is disposed on the second planarization layer 119 and the cathode electrode CAT in the entire area including the transmission hole TH.

That is, the first data line SDL1 of the second layer may be disposed on the gate line GL5 of the first layer. Further, the second data line SDL2 of the third layer may be disposed on the first data line SDL1 of the second layer.

In the meantime, as shown in FIG. 5, the plurality of gate connection lines GCL1, GCL2, and GCL3 and the plurality of gate jumping lines GJL1 and GJL2 may be disposed on the second layer. To be more specific, as shown in FIG. 7, the third gate connection line GCL3 and the second gate jumping line GJL2 may be disposed on the second layer. Further, the second gate jumping line GJL2 is in contact with the fifth gate line GL5 through a contact hole and the third gate connection line GCL3 is also in contact with the fifth gate line GL5 through a contact hole.

Therefore, all the second gate line GL2 and the fifth gate line GL5, the second gate jumping line GJL2, and the third gate connection line GCL3 may transmit the emission signal EM.

In the meantime, as shown in FIG. 5, a plurality of transmission holes TH may be disposed in the transmission unit TA of the first display area A1.

Further, as described above, the number of the plurality of gate connection lines GCL1, GCL2, and GCL3 disposed in the transmission unit TA of the first display area A1 may be smaller than the number of the plurality of gate lines GL1 to GL5.

That is, an area of the first display area A1 is limited, but the number of wiring lines to be disposed is reduced so that an area of each of the plurality of transmission holes TH may be relatively increased.

Unlike the display device according to the example embodiment of the present disclosure, if the number of the plurality of gate connection lines GCL1, GCL2, and GCL3 disposed in the transmission unit TA of the first display area A1 is equal to the number of the plurality of gate lines GL1 to GL5, an area in the transmission unit TA of the first display area A1 occupied by the plurality of gate connection lines GCL1, GCL2, and GCL3 is relatively large. Therefore, the area of the transmission hole TH may be relatively small.

That is, if the number of the plurality of gate connection lines GCL1, GCL2, and GCL3 disposed in the transmission unit TA of the first display area A1 is equal to the number of the plurality of gate lines GL1 to GL5, an area ratio of the transmission hole TH may be measured as 23.9%.

However, as in the display device according to the example embodiment of the present disclosure, if the number of the plurality of gate connection lines GCL1, GCL2, and GCL3 disposed in the transmission unit TA of the first display area A1 is smaller than the number of the plurality of gate lines GL1 to GL5, an area in the transmission unit TA of the first display area A1 occupied by the plurality of gate connection lines GCL1, GCL2, and GCL3 is relatively reduced. Therefore, the area of the transmission hole TH may be relatively large.

That is, if the number of the plurality of gate connection lines GCL1, GCL2, and GCL3 disposed in the transmission unit TA of the first display area A1 is smaller than the number of the plurality of gate lines GL1 to GL5, an area ratio of the transmission hole TH may be measured as 52.4%.

That is, according to the example embodiment of the present disclosure, the area ratio of the transmission hole TH is increased by 21.4% so that an amount of light which is detectable by the sensor may be increased.

As a result, according to the example embodiment of the present disclosure, the sensing performance of the sensor may be improved.

In the meantime, a shape of the plurality of transmission holes TH may be determined according to a shape of the second data line SDL2.

As illustrated in FIG. 5, the shape of the second data line SDL2 is circular so that a boundary of the plurality of transmission holes TH may be also circular.

However, the shape of the plurality of transmission holes TH may be deformed to various shapes, such as an elliptical shape without being limited to the circular shape.

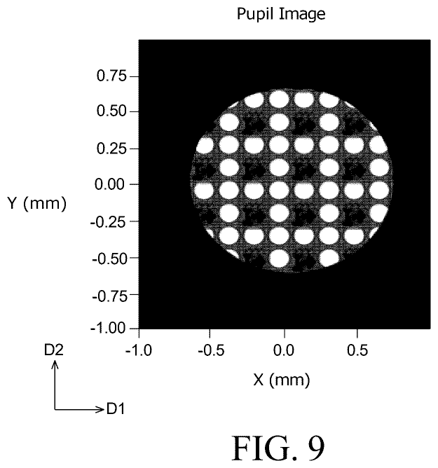

FIG. 9 is a view illustrating a placement relationship of a transmission unit in a display device according to an example embodiment of the present disclosure.

As shown in FIG. 5, the plurality of transmission holes TH may be continuously disposed not only in the first direction D1, but also in the second direction D2. That is, the plurality of transmission holes TH may be disposed in a matrix.

Accordingly, as shown in FIG. 9, the transmission unit may be disposed in the first display area A1 in a matrix to be continuously disposed in the first direction D1 and the second direction D2.

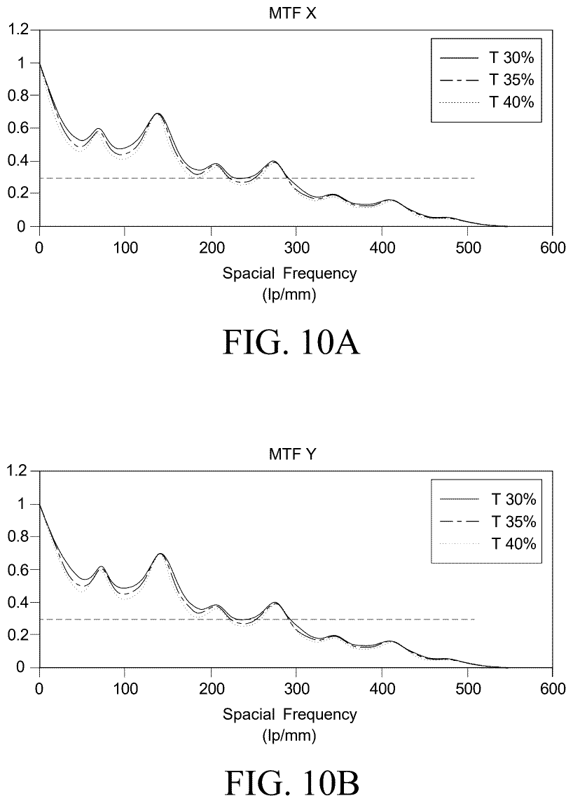

FIGS. 10A and 10B are graphs illustrating a modulation transfer function (MTF) of a transmission unit TA in a display device according to an example embodiment of the present disclosure.

MTF means the ability of a lens to show a contrast of a sample using spatial frequency (lp/mm) as an image and the unit is %.

In the meantime, the target MTF of the display device is necessary to be 30% or higher at a spatial frequency of 120 lp/mm or lower. In the display device, if the MTF of the transmission unit TA is 30% or lower at 120 lp/mm or lower, there is a problem in that the optical performance of the sensor is degraded.

Specifically, in FIG. 10A, the MTF of the transmission unit TA is measured with respect to the X axis which is the first direction and in FIG. 10B, the MTF is measured with respect to the Y axis which is the second direction.

Further, as shown in FIGS. 10A and 10B, the MTF was measured when the transmittance T of the transmission unit TA is 30%, 35%, and 40%.

As shown in FIG. 10A, as in the display device according to the example embodiment of the present disclosure, when the transmission holes TH are continuously disposed in the first direction D1 and the second direction D2, and the transmittance T is 30%, 35%, and 40%, it is confirmed that the MTF based on the X-axis is 30% or larger at the spatial frequency of 120 lp/mm or lower.

Further, as shown in FIG. 10B, as in the display device according to the example embodiment of the present disclosure, when the transmission holes TH are continuously disposed in the first direction D1 and the second direction D2, and the transmittance T is 30%, 35%, and 40%, it is confirmed that the MTF based on the Y-axis is 30% or larger at the spatial frequency of 120 lp/mm or lower.

That is, it is confirmed that the display device according to the example embodiment of the present disclosure achieves a MTF target value. Therefore, it is confirmed that the display device according to the example embodiment of the present disclosure includes transmission holes TH which are continuously disposed in the first direction D1 and the second direction D2 so that the optical performance of the sensor may be improved.

Hereinafter, a display device according to another example embodiment of the present disclosure will be described.

A display device according to another example embodiment of the present disclosure is different from the display device according to the example embodiment of the present disclosure in that a shape of a second data line and a shape of the plurality of transmission holes are different. Accordingly, in the display device according to another example embodiment of the present disclosure and the display device according to the example embodiment of the present disclosure, the description will be made below by denoting like component with like reference numeral and a different component with different reference numeral.

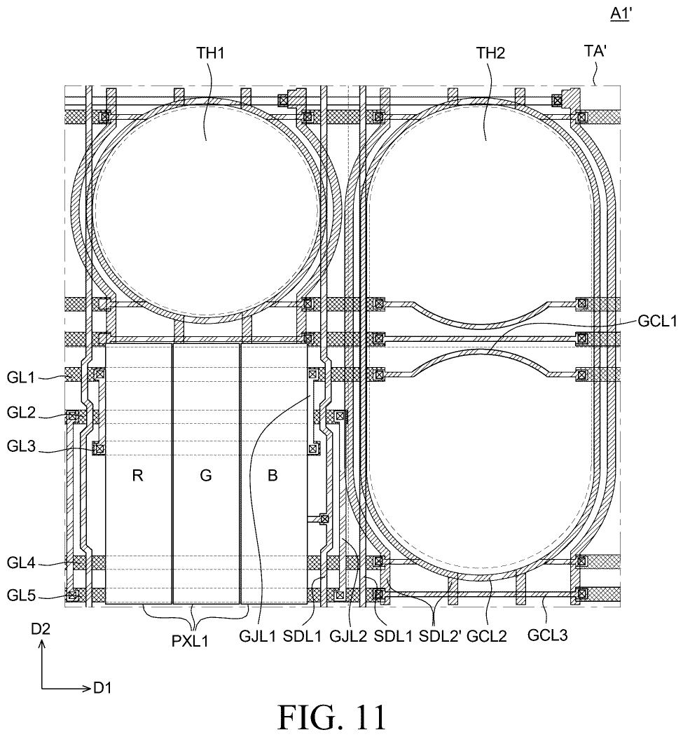

FIG. 11 is a view illustrating a detailed layout of a first display area of a display panel of a display device according to another example embodiment of the present disclosure.

In a transmission unit TA′ of the first display area A1, a plurality of transmission holes TH1 and TH2 may be disposed. Further, a shape of the plurality of transmission holes TH1 and TH2 may be determined according to a shape of a second data line SDL2′.

As illustrated in FIG. 11, the shape of a second data line SDL2′ is circular or elliptical so that a boundary of the plurality of transmission holes TH1 and TH2 may be also circular or elliptical.

In other words, in the display device according to another example embodiment of the present disclosure, the plurality of transmission holes TH1 and TH2 may include a circular first transmission hole TH1 and an elliptical second transmission hole TH2. Further, the size of the second transmission hole TH2 may be larger than the size of the first transmission hole TH1. Further, the elliptical second transmission hole TH2 may have a major axis in the second direction D2. Further, the first transmission hole TH1 and the second transmission hole TH2 may be alternately disposed in the first direction and the plurality of second transmission holes TH2 may be continuously disposed in the second direction D2.

Accordingly, in the first display area A1′ of the display panel of the display device according to another example embodiment of the present disclosure, the transmission unit TA′ may be disposed in a matrix to be continuously disposed in the first direction D1 and the second direction D2.

Further, a ratio of the transmissive area of the first transmission hole TH1 is 56.2% and a ratio of the transmissive area of the second transmission hole TH2 is 65.0% so that in the first display area A1′ of the display panel of the display device according to another example embodiment of the present disclosure, the ratio of the transmissive area of the transmission unit TA′ may be 46.5%.

Accordingly, according to another example embodiment of the present disclosure, the area of the transmission holes TH1 and TH2 is increased by 21.4% of the area of the transmission hole TH of the example embodiment of the present disclosure, so that an amount of light which is detectable by the sensor may be further increased.

As a result, according to another example embodiment of the present disclosure, the sensing performance of the sensor may be further improved.

The example embodiments of the present disclosure can also be described as follows:

According to an aspect of the present disclosure, a display device includes at least one sensor; and a display panel divided into a first display area overlapped with the at least one sensor and a second display area, wherein: in the first display area, a first pixel unit including at least one pixel and a transmission unit are disposed; in the second display area, a second pixel unit including at least one pixel is disposed; and the transmission unit is continuously disposed in a first direction and a second direction which is different from the first direction, thereby improving the modulation transfer function (MTF) characteristic of the sensor.

In the first pixel unit, a plurality of signal lines electrically connected to the at least one pixel in the first pixel unit may be disposed. In the transmission unit, a plurality of signal connection lines electrically connected to the plurality of signal lines may be disposed. The number of the plurality of signal connection lines may be smaller than the number of the plurality of signal lines.

Wiring lines configured to output the same signal, among the plurality of signal lines, may be connected by one signal connection line.

All the plurality of signal lines and the plurality of signal connection lines may extend in the first direction.

Wiring lines configured to output the same signal, among the plurality of signal lines, may be connected by a signal jumping line.

The signal jumping line may extend in the second direction.

The plurality of signal lines may be disposed on a first layer, and the plurality of signal connection lines may be disposed on a second layer on the first layer.

A gate electrode of a transistor included in the at least one pixel in the first pixel unit may be disposed on the first layer, and a source electrode and a drain electrode of the transistor included in the at least one pixel in the first pixel unit may be disposed on the second layer.

A plurality of transmission holes may be disposed in the transmission unit, and a boundary of the plurality of transmission holes may be formed by a wiring line formed on a third layer on the second layer.

The plurality of transmission holes may have a circular shape and may be continuously disposed in the first direction and the second direction.

The plurality of transmission holes may include a first transmission hole and a second transmission hole having different sizes, and at least one of the first transmission hole and the second transmission hole have an elliptical shape having a major axis in the second direction.

The first transmission hole and the second transmission hole may be alternately disposed in the first direction.

According to another embodiment of the present disclosure, a display device includes at least one sensor; and a display panel including a plurality of gate lines extending in a first direction, a plurality of data lines extending in a second direction, and a plurality of pixels, wherein in a transmissive area of the display panel which overlaps the at least one sensor, a plurality of transmission holes are disposed in the first direction and the second direction, thereby improving the modulation transfer function (MTF) characteristic of the sensor.

Each of the plurality of transmission holes may have a circular shape or an elliptical shape.

The plurality of transmission holes may include a first transmission hole and a second transmission hole having different sizes, and the first transmission hole and the second transmission hole may be alternately disposed.

In the transmissive area, a plurality of gate lines configured to output the same signal may be integrated by one gate connection line.

In the transmissive area, a plurality of gate lines configured to output the same signal is connected by one gate jumping line.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
at least one sensor; and
a display panel divided into:
a first display area overlapped with the at least one sensor; and
a second display area,
wherein:
in the first display area, a first pixel unit including at least one pixel and a transmission unit are disposed;
in the second display area, a second pixel unit including at least one pixel is disposed; and
the transmission unit is continuously disposed in a first direction and a second direction which is different from the first direction.

2. The display device according to claim 1, wherein:
in the first pixel unit, a plurality of signal lines electrically connected to the at least one pixel in the first pixel unit are disposed;
in the transmission unit, a plurality of signal connection lines electrically connected to the plurality of signal lines are disposed; and
the number of the plurality of signal connection lines is smaller than the number of the plurality of signal lines.

3. The display device according to claim 2,
wherein wiring lines configured to output the same signal, among the plurality of signal lines, are connected by one signal connection line.

4. The display device according to claim 2,
wherein all the plurality of signal lines and the plurality of signal connection lines extend in the first direction.

5. The display device according to claim 4,
wherein wiring lines configured to output the same signal, among the plurality of signal lines, are connected by a signal jumping line.

6. The display device according to claim 5,
wherein the signal jumping line extends in the second direction.

7. The display device according to claim 2,
wherein the plurality of signal lines are disposed on a first layer, and the plurality of signal connection lines are disposed on a second layer on the first layer.

8. The display device according to claim 7, wherein:
a gate electrode of a transistor included in the at least one pixel in the first pixel unit is disposed on the first layer; and
a source electrode and a drain electrode of the transistor included in the at least one pixel in the first pixel unit are disposed on the second layer.

9. The display device according to claim 7, wherein:
a plurality of transmission holes are disposed in the transmission unit; and
a boundary of the plurality of transmission holes is formed by a wiring line formed on a third layer on the second layer.

10. The display device according to claim 9,
wherein the plurality of transmission holes have a circular shape and are continuously disposed in the first direction and the second direction.

11. The display device according to claim 9, wherein:
the plurality of transmission holes include a first transmission hole and a second transmission hole having different sizes; and
at least one of the first transmission hole and the second transmission hole has an elliptical shape having a major axis in the second direction.

12. The display device according to claim 11,
wherein the first transmission hole and the second transmission hole are alternately disposed in the first direction.

13. A display device, comprising:
at least one sensor; and
a display panel including a plurality of gate lines extending in a first direction, a plurality of data lines extending in a second direction, and a plurality of pixels,
wherein, in a transmissive area of the display panel which overlaps the at least one sensor, a plurality of transmission holes are disposed in the first direction and the second direction.

14. The display device according to claim 13,
wherein each of the plurality of transmission holes has a circular shape or an elliptical shape.

15. The display device according to claim 13, wherein:
the plurality of transmission holes include a first transmission hole and a second transmission hole having different sizes; and
the first transmission hole and the second transmission hole are alternately disposed.

16. The display device according to claim 13,
wherein, in the transmissive area, a plurality of gate lines configured to output the same signal are integrated by one gate connection line.

17. The display device according to claim 13,
wherein, in the transmissive area, a plurality of gate lines configured to output the same signal are connected by one gate jumping line.
